(19) United States
(12) Patent Application Publication
(10) Pub. No.: US 2025/0234512 A1
(43) Pub. Date: Jul. 17, 2025

(54) MEMORY DEVICE INCLUDING WORD LINE STRUCTURE HAVING HIGH-K GATE DIELECTRIC LAYER AND METHOD FOR PREPARING THE SAME

(71) Applicant: NANYA TECHNOLOGY CORPORATION, NEW TAIPEI CITY (TW)

(72) Inventor: YING-CHENG CHUANG, TAOYUAN CITY (TW)

(21) Appl. No.: 18/414,599

(22) Filed: Jan. 17, 2024

(51) Int. Cl. H10B 12/00

(52) U.S. Cl. CPC H10B 12/34; H10B 12/0335; H10B 12/053; H10B 12/315; H10B 12/485

(57) ABSTRACT

A memory device includes a semiconductor substrate having an active area, and a word line structure extending across the active area. The word line structure includes a metal gate electrode layer and a high-k gate dielectric layer surrounding the metal gate electrode layer. The memory device also includes a first source/drain region and a second source/drain region disposed in the active area and at opposite sides of the word line structure. The memory device further includes a bit line structure disposed over and electrically connected to the first source/drain region, and a capacitor disposed over and electrically connected to the second source/drain region.

### TECHNICAL FIELD

The present disclosure relates to a memory device and a method for preparing the same, and more particularly, to a memory device including a word line structure having a high-k gate dielectric layer and a method for preparing the same.

### DISCUSSION OF THE BACKGROUND

Due to structural simplicity, dynamic random access memories (DRAMs) can provide more memory cells per unit chip area than other types of memories, such as static random access memories (SRAMs). A DRAM is constituted by a plurality of DRAM cells, each of which includes a capacitor for storing information and a transistor coupled to the capacitor for regulating when the capacitor is charged or discharged. During a read operation, a word line (WL) is asserted, turning on the transistor. The enabled transistor allows the voltage across the capacitor to be read by a sense amplifier through a bit line (BL). During a write operation, the data to be written is provided on the BL while the WL is asserted.

To satisfy the demand for greater memory storage, the dimensions of the DRAM memory cells have continuously shrunk so that the packing densities of these DRAMs have increased considerably. However, the manufacturing and integration of memory devices involve many complicated steps and operations. Integration in memory devices becomes increasingly complicated. An increase in complexity of manufacturing and integration of the memory device may cause deficiencies. Accordingly, there is a continuous need to improve the structure and the manufacturing process of memory devices so that the deficiencies can be addressed, and the performance can be enhanced.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a memory device is provided. The memory device includes a semiconductor substrate having an active area, and a word line structure extending across the active area. The word line structure includes a metal gate electrode layer and a high-k gate dielectric layer surrounding the metal gate electrode layer. The memory device also includes a first source/drain region and a second source/drain region disposed in the active area and at opposite sides of the word line structure. The memory device further includes a bit line structure disposed over and electrically connected to the first source/drain region, and a capacitor disposed over and electrically connected to the second source/drain region.

In an embodiment, the high-k gate dielectric layer has a first width over a top surface of the metal gate electrode and a second width below the top surface of the metal gate electrode, wherein the second width is greater than the first width. In an embodiment, the memory device further includes a bit line contact disposed between the first source/drain region and the bit line structure, wherein the bit line contact is in direct contact with the high-k gate dielectric layer. In an embodiment, the memory device further includes a dielectric layer covering the word line structure, wherein a portion of the high-k gate dielectric layer is sandwiched between the dielectric layer and the bit line contact. In an embodiment, the dielectric layer has a portion surrounded by the high-k gate dielectric layer, and a width of the portion of the dielectric layer is greater than a width of the metal gate electrode layer.

In an embodiment, the memory device further includes a mask layer disposed between the second source/drain region and the capacitor, wherein the mask layer is in direct contact with the high-k gate dielectric layer. In an embodiment, the high-k gate dielectric layer has a third width adjacent to the mask layer and a fourth width adjacent to the second source/drain region, wherein the fourth width is greater than the third width. In an embodiment, a top surface of the high-k gate dielectric layer is substantially level with a top surface of the mask layer.

In another embodiment of the present disclosure, a memory device is provided. The memory device includes a semiconductor substrate having an active area, and a word line structure extending across the active area. The word line structure includes a metal gate electrode layer and a high-k gate dielectric layer surrounding the metal gate electrode layer. The memory device also includes a first source/drain region and a second source/drain region disposed in the active area and at opposite sides of the word line structure. The memory device further includes a dielectric layer disposed over the semiconductor substrate and covering the word line structure. An interface between the dielectric layer and the high-k gate dielectric layer is substantially level with an interface between the dielectric layer and the metal gate electrode layer. In addition, the memory device includes a bit line structure disposed over and electrically connected to the first source/drain region, and a capacitor disposed over and electrically connected to the second source/drain region.

In an embodiment, the high-k gate dielectric layer has a first width over a top surface of the metal gate electrode and a second width below the top surface of the metal gate electrode, and wherein the second width is greater than the first width. In an embodiment, the memory device further includes a bit line contact penetrating through the dielectric layer to electrically connect the first source/drain region and the bit line structure, wherein the bit line contact is in direct contact with the high-k gate dielectric layer.

In an embodiment, the memory device further includes a mask layer disposed between the second source/drain region and the dielectric layer, wherein the mask layer is in direct contact with the high-k gate dielectric layer. In an embodiment, the high-k gate dielectric layer has a third width adjacent to the mask layer and a fourth width adjacent to the second source/drain region, wherein the fourth width is greater than the third width. In an embodiment, a top surface of the high-k gate dielectric layer is substantially level with a top surface of the mask layer. In an embodiment, the memory device further includes a capacitor contact penetrating through the dielectric layer and the mask layer to electrically connect the second source/drain region and the capacitor.

In yet another embodiment of the present disclosure, a method for preparing a memory device is provided. The method includes forming a doped region in a semiconductor substrate, and performing a first etching process on the semiconductor substrate to form a trench. The trench extends across the doped region such that a first source/drain region and a second source/drain region are formed in the doped region and at opposite sides of the trench. The method also includes forming a high-k dielectric material lining the trench, and filling the trench with a metal material. The method further includes performing a second etching process on the high-k dielectric material and the metal material to form a recess. Remaining portions of the high-k dielectric material and the metal material form a high-k gate dielectric layer of a word line structure and a metal gate electrode layer of the word line structure, respectively, and a width of the recess is greater than a width of the metal gate electrode layer. In addition, the method includes forming a bit line structure over and electrically connected to the first source/drain region, and forming a capacitor over and electrically connected to the second source/drain region.

In an embodiment, the high-k gate dielectric layer has a first width over a top surface of the metal gate electrode and a second width below the top surface of the metal gate electrode, and the second width is greater than the first width. In an embodiment, the method further includes forming a mask material over the semiconductor substrate and covering the doped region before the first etching process is performed, wherein the trench penetrates through the mask material, and a remaining portion of the mask material forms a mask layer after the first etching process is performed. In an embodiment, a top surface and a sidewall of the mask layer are covered by the high-k dielectric material before the second etching process is performed. In an embodiment, the top surface of the mask layer is exposed after the second etching process is performed.

In an embodiment, the method further includes forming a dielectric layer over the semiconductor substrate after the second etching process is performed, wherein the recess is filled by a portion of the dielectric layer. In an embodiment, a width of the portion of the dielectric layer is greater than the width of the metal gate electrode layer. In an embodiment, an interface between the dielectric layer and the high-k gate dielectric layer is substantially level with an interface between the dielectric layer and the metal gate electrode layer. In an embodiment, the method further includes forming a bit line contact penetrating through the dielectric layer to contact the first source/drain region, wherein the bit line contact is in direct contact with the high-k gate dielectric layer.

Embodiments of a memory device and method for preparing the same are provided in the disclosure. In some embodiments, the memory device includes a word line structure disposed in a semiconductor substrate. The word line structure includes a metal gate electrode layer and a high-k gate dielectric layer surrounding the metal gate electrode layer. Therefore, gate-to-substrate leakage current can be reduced while suppressing channel leakage current and enlarging the channel length. As a result, the performance of the memory device can be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view illustrating a memory device, in accordance with some embodiments.

FIG. 2 is a cross-sectional view illustrating the memory device along the sectional line A-A′ in FIG. 1, in accordance with some embodiments.

FIG. 3 is an enlarged view of a portion of the memory device in FIG. 2, in accordance with some embodiments.

FIG. 4 is an enlarged view of another portion of the memory device in FIG. 2, in accordance with some embodiments.

FIG. 5 is a flow diagram illustrating a method for preparing a memory device, in accordance with some embodiments.

FIG. 6 is a top view illustrating an intermediate stage of forming doped regions in a semiconductor substrate during the formation of the memory device, in accordance with some embodiments.

FIG. 7 is a cross-sectional view illustrating an intermediate stage in the formation of the memory device along the sectional line A-A′ in FIG. 6, in accordance with some embodiments.

FIG. 8 is a top view illustrating an intermediate stage of sequentially forming a mask material and a patterned mask over the semiconductor substrate during the formation of the memory device, in accordance with some embodiments.

FIG. 9 is a cross-sectional view illustrating an intermediate stage in the formation of the memory device along the sectional line A-A′ in FIG. 8, in accordance with some embodiments.

FIG. 10 is a top view illustrating an intermediate stage of etching the mask material and the semiconductor substrate to form trenches across the doped regions, and forming source/drain regions during the formation of the memory device, in accordance with some embodiments.

FIG. 11 is a cross-sectional view illustrating an intermediate stage in the formation of the memory device along the sectional line A-A′ in FIG. 10, in accordance with some embodiments.

FIG. 12 is a top view illustrating an intermediate stage of forming a high-k dielectric material lining the trenches during the formation of the memory device, in accordance with some embodiments.

FIG. 13 is a cross-sectional view illustrating an intermediate stage in the formation of the memory device along the sectional line A-A′ in FIG. 12, in accordance with some embodiments.

FIG. 14 is a cross-sectional view illustrating an intermediate stage of filling the trenches with a metal material during the formation of the memory device, in accordance with some embodiments.

FIG. 15 is a top view illustrating an intermediate stage of recessing the high-k dielectric material and the metal material to form word line structures during the formation of the memory device, in accordance with some embodiments.

FIG. 16 is a cross-sectional view illustrating an intermediate stage in the formation of the memory device along the sectional line A-A′ in FIG. 15, in accordance with some embodiments.

FIG. 17 is an enlarged view of a portion of the memory device in FIG. 16, in accordance with some embodiments.

FIG. 18 is a cross-sectional view illustrating an intermediate stage of forming a dielectric layer covering the word line structures during the formation of the memory device, in accordance with some embodiments.

FIG. 19 is a top view illustrating an intermediate stage of etching the dielectric layer to form bit line contact openings during the formation of the memory device, in accordance with some embodiments.

FIG. 20 is a cross-sectional view illustrating an intermediate stage in the formation of the memory device along the sectional line A-A′ in FIG. 19, in accordance with some embodiments.

FIG. 21 is a top view illustrating an intermediate stage of forming bit line contacts, bit line structures and dielectric spacers during the formation of the memory device, in accordance with some embodiments.

FIG. 22 is a cross-sectional view illustrating an intermediate stage in the formation of the memory device along the sectional line A-A′ in FIG. 21, in accordance with some embodiments.

FIG. 23 is a top view illustrating an intermediate stage of forming a dielectric layer surrounding the bit line structures, and removing the dielectric spacers to form air gaps during the formation of the memory device, in accordance with some embodiments.

FIG. 24 is a cross-sectional view illustrating an intermediate stage in the formation of the memory device along the sectional line A-A′ in FIG. 23, in accordance with some embodiments.

FIG. 25 is a top view illustrating an intermediate stage of forming a dielectric layer covering the bit line structures, and forming capacitor contact openings during the formation of the memory device, in accordance with some embodiments.

FIG. 26 is a cross-sectional view illustrating an intermediate stage in the formation of the memory device along the sectional line A-A′ in FIG. 25, in accordance with some embodiments.

FIG. 27 is a top view illustrating an intermediate stage of forming capacitor contacts, forming a dielectric layer over the capacitor contacts, and forming capacitor openings in the dielectric layer during the formation of the memory device, in accordance with some embodiments.

FIG. 28 is a cross-sectional view illustrating an intermediate stage in the formation of the memory device along the sectional line A-A′ in FIG. 27, in accordance with some embodiments.

FIG. 29 is a partial schematic illustration of an exemplary integrated circuit, including an array of memory cells in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

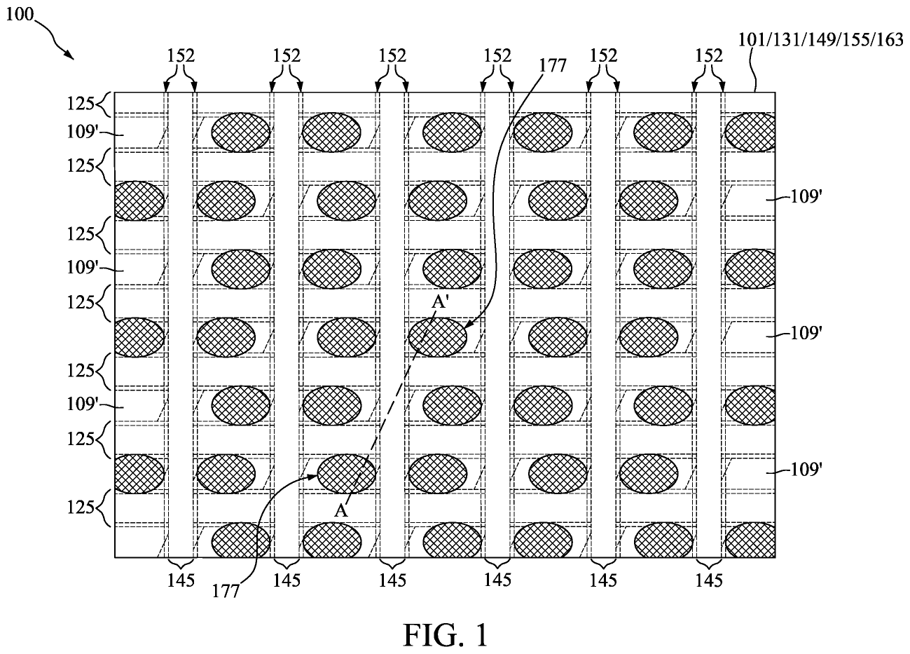

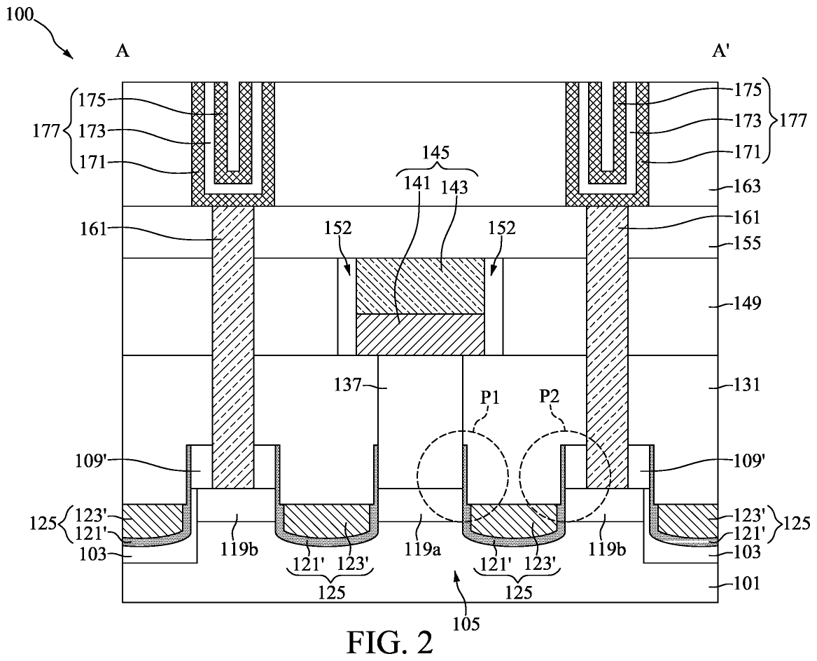

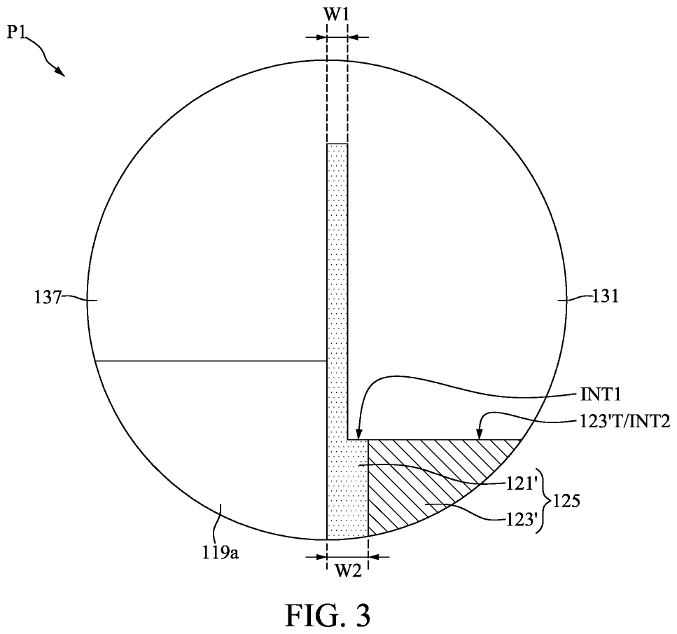

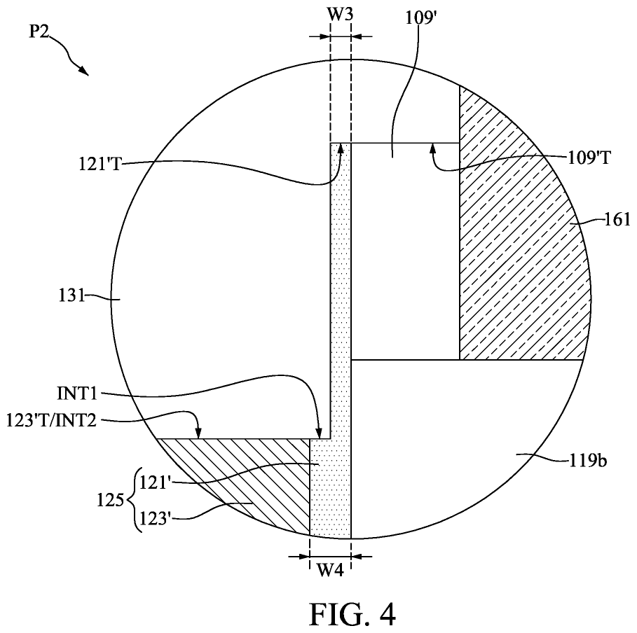

FIG. 1 is a top view illustrating a memory device 100, FIG. 2 is a cross-sectional view illustrating the memory device 100 along the sectional line A-A′ in FIG. 1, in accordance with some embodiments. FIG. 3 is an enlarged view of a portion P1 of the memory device 100 in FIG. 2, and FIG. 4 is an enlarged view of a portion P2 of the memory device 100 in FIG. 2, in accordance with some embodiments.

As shown in FIGS. 1 and 2, the memory device 100 includes a semiconductor substrate 101, an isolation structure 103 disposed in the semiconductor substrate 101 defining a plurality of active areas 105, a plurality of word line structures 125 (i.e., the gate structures) extending across the active areas 105, and a plurality of source/drain regions 119a and 119b in the active areas 105 separated by the word line structures 125. In some embodiments, each of the active areas 105 includes two source/drain regions 119b and one source/drain region 119a disposed between the source/drain regions 119b. Moreover, each of the word line structures 125 includes a high-k gate dielectric layer 121′ and a metal gate electrode layer 123′ surrounded by the high-k gate dielectric layer 121′.

In some embodiments, the memory device 100 includes mask layers 109′ disposed over the source/drain regions 119b. In some embodiments, the memory device 100 includes a dielectric layer 131 covering the mask layers 109′ and the word line structures 125, and a dielectric layer 149 disposed over the dielectric layer 131. In some embodiments, the memory device 100 includes a plurality of bit line contacts 137 penetrating through the dielectric layer 131 to contact the source/drain regions 119a, and a plurality of bit line structures 145 penetrating through the dielectric layer 149 to contact the bit line contacts 137. In some embodiments, each of the bit line structures 145 includes a lower bit line layer 141 and an upper bit line layer 143 disposed over the lower bit line layer 141. In some embodiments, the bit line structures 145 are separated from the dielectric layer 149 by air gaps 152.

In addition, the memory device 100 includes a dielectric layer 155 disposed over the dielectric layer 149, a plurality of capacitor contacts 161 penetrating through the dielectric layers 155, 149, 131 and the mask layers 109′ to contact the source/drain regions 119b, and a dielectric layer 163 disposed over the dielectric layer 155, in accordance with some embodiments. The memory device 100 further includes a plurality of capacitors 177 disposed in the dielectric layer 163 to contact the capacitor contacts 161, as shown in FIGS. 1 and 2 in accordance with some embodiments.

In some embodiments, each of the capacitors 177 includes a bottom electrode 171, a top electrode 175 disposed over and surrounded by the bottom electrode 171, and a dielectric layer 173 disposed between and in direct contact with the bottom electrode 171 and the top electrode 175. In some embodiments, the bit line structures 145 are electrically connected to the source/drain regions 119a through the bit line contacts 137, and the capacitors 177 are electrically connected to the source/drain regions 119b through the capacitor contacts 161. In some embodiments, the memory device 100 is part of a DRAM.

As shown in FIG. 3, the high-k gate dielectric layer 121′ of the word line structure 125 has a first width W1 over the top surface 123′T of the metal gate electrode layer 123′ of the word line structure 125, and a second width W2 below the top surface 123′T of the metal gate electrode layer 123′ of the word line structure 125. In some embodiments, the second width W2 is greater than the first width W1. Moreover, the interface INT1 between the dielectric layer 131 and the high-k gate dielectric layer 121′ of the word line structure 125 is substantially level with the interface INT2 between the dielectric layer 131 and the metal gate electrode layer 123′ of the word line structure 125, in accordance with some embodiments. Within the context of this disclosure, the word “substantially” means preferably at least 90%, more preferably 95%, even more preferably 98%, and most preferably 99%.

As shown in FIG. 4, the high-k gate dielectric layer 121′ of the word line structure 125 has a third width W3 over the top surface 123′T of the metal gate electrode layer 123′ of the word line structure 125, and a fourth width W4 below the top surface 123′T of the metal gate electrode layer 123′ of the word line structure 125. In some embodiments, the fourth width W4 is greater than the third width W3. In some embodiments, the interface INT1 between the dielectric layer 131 and the high-k gate dielectric layer 121′ of the word line structure 125 is substantially level with the interface INT2 between the dielectric layer 131 and the metal gate electrode layer 123′ of the word line structure 125. In addition, the top surface 121′T of the high-k gate dielectric layer 121′ of the word line structure 125 is substantially level with the top surface 109′T of the mask layer 109′, in accordance with some embodiments.

Embodiments of the memory device 100 and method for preparing the same are provided in the disclosure. In some embodiments, the memory device 100 includes the word line structures 125 disposed in the semiconductor substrate 101, and the word line structures 125 include the metal gate electrode layers 123′ and the high-k gate dielectric layers 121′ surrounding the metal gate electrode layers 123′. Therefore, gate-to-substrate leakage current can be reduced while suppressing channel leakage current and enlarging the channel length, which are advantages of the buried word line structures (i.e., the word line structures 125). In addition, the air gaps 152 may help to reduce parasitic capacitance and correspondingly improve device performance (e.g., by reducing signal noise). As a result, the performance of the memory device 100 can be improved.

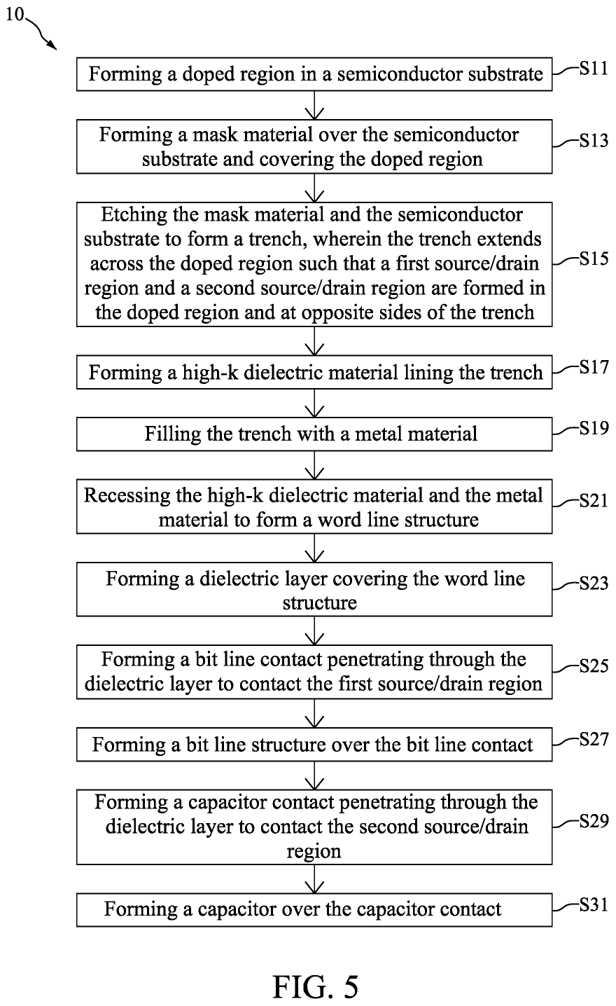

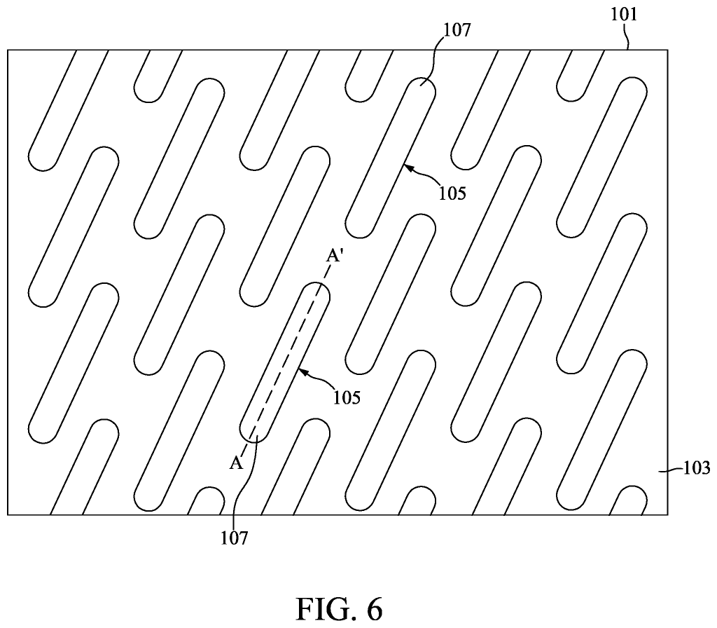

FIG. 5 is a flow diagram illustrating a method 10 for preparing the memory device 100, and the method 10 includes steps S11, S13, S15, S17, S19, S21, S23, S25, S27, S29 and S31, in accordance with some embodiments. The steps S11 to S31 of FIG. 5 are elaborated in connection with FIGS. 6 to 28.

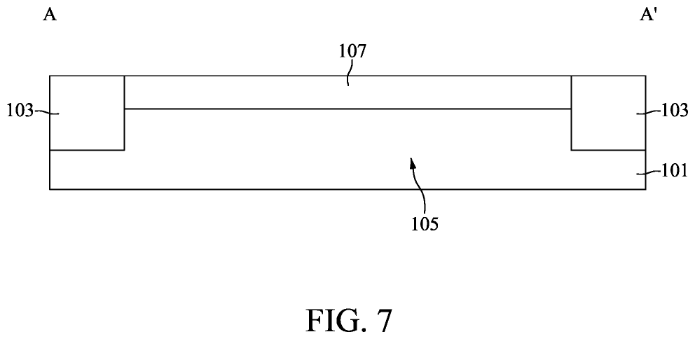

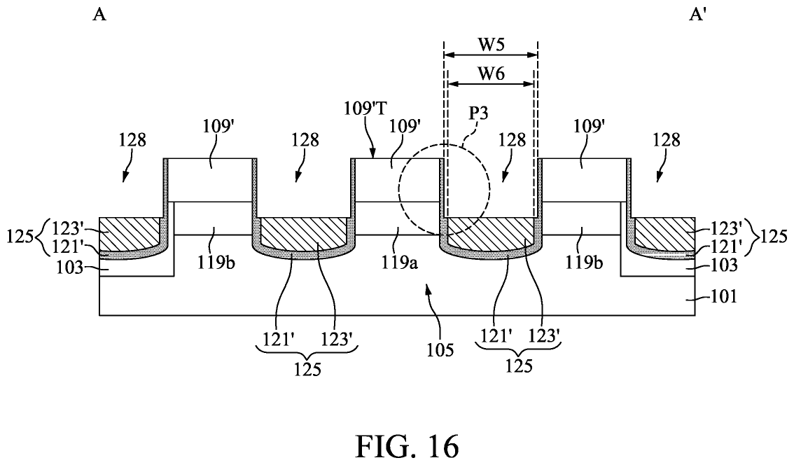

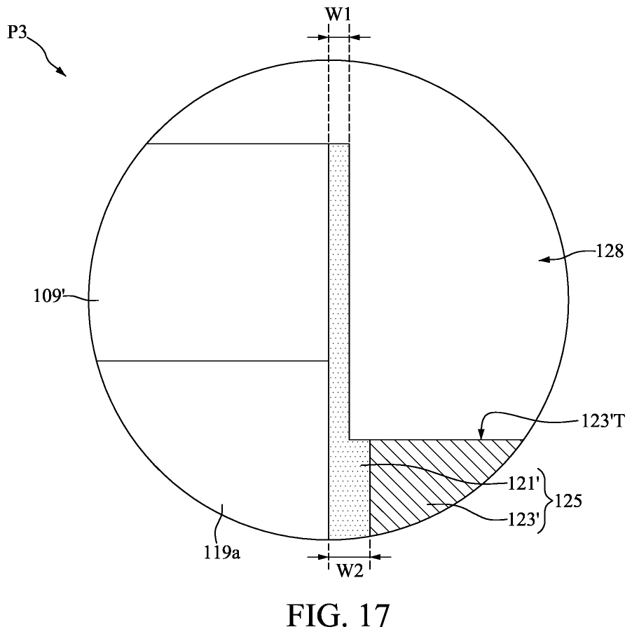

FIGS. 6, 8, 10, 12, 15, 19, 21, 23, 25 and 27 are top views illustrating intermediate stages in the formation of the memory device 100, and FIGS. 7, 9, 11, 13, 14, 16, 18, 20, 22, 24, 26 and 28 are cross-sectional views illustrating intermediate stages in the formation of the memory device 100, in accordance with some embodiments. It should be noted that FIGS. 7, 9, 11, 13, 16, 20, 22, 24, 26 and 28 are cross-sectional views along the sectional line A-A′ of FIGS. 6, 8, 10, 12, 15, 19, 21, 23, 25 and 27, respectively. Moreover, FIG. 17 is an enlarged view of a portion P3 of the memory device 100 in FIG. 16, in accordance with some embodiments.

As shown in FIGS. 6 and 7, a semiconductor substrate 101 is provided. The semiconductor substrate 101 may be a semiconductor wafer such as a silicon wafer. Alternatively or additionally, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the semiconductor substrate 101 includes an epitaxial layer. For example, the semiconductor substrate 101 has an epitaxial layer overlying a bulk semiconductor. In some embodiments, the semiconductor substrate 101 is a semiconductor-on-insulator substrate which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

Still referring to FIGS. 6 and 7, an isolation structure 103 is formed in the semiconductor substrate 101 to define a plurality of active areas 105, and the isolation structure 103 is a shallow trench isolation (STI) structure, in accordance with some embodiments. In addition, the isolation structure 103 may include silicon oxide, silicon nitride, silicon oxynitride or another suitable dielectric material, and the formation of the isolation structure 103 may include forming a patterned mask (not shown) over the semiconductor substrate 101, etching the semiconductor substrate 101 to form openings (not shown) by using the patterned mask as a mask, depositing a dielectric material in the openings and over the semiconductor substrate 101, and planarizing the dielectric material until the semiconductor substrate 101 is exposed.

Moreover, a plurality of doped regions 107 are formed in the active areas 105 defined by the isolation structure 103. The respective step is illustrated as the step S11 in the method 10 shown in FIG. 5. In some embodiments, the doped regions 107 are formed by one or more ion implantation processes, and P-type dopants, such as boron (B), gallium (Ga), or indium (In), or N-type dopants, such as phosphorous (P) or arsenic (As), can be implanted in the active areas 105 to form the doped regions 107, depending on the conductivity type of the memory device 100. In addition, the doped regions 107 will become the source/drain regions of the memory device 100 in the subsequent processes.

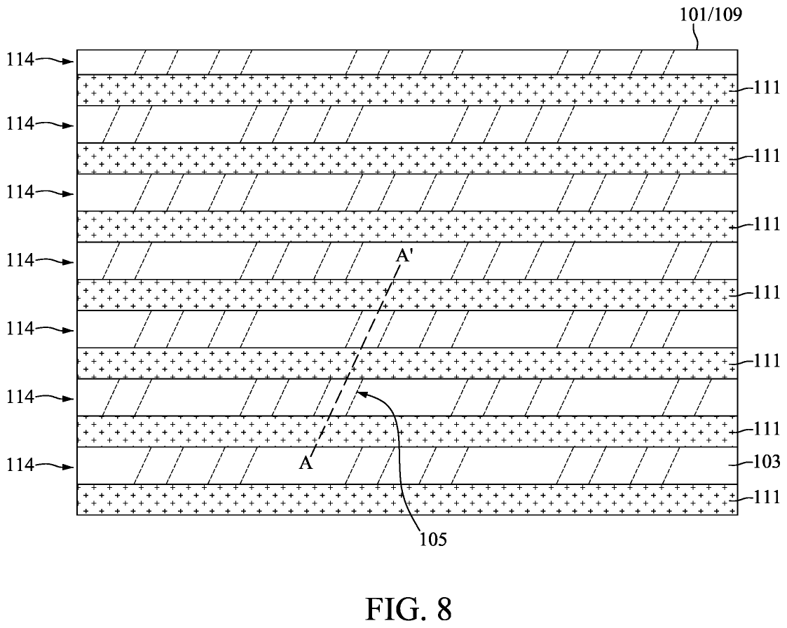

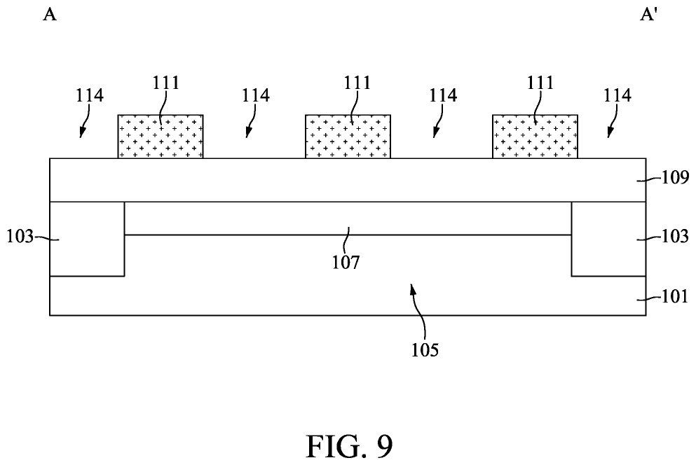

After the doped regions 107 are formed, a mask material 109 is formed over the semiconductor substrate 101, as shown in FIGS. 8 and 9 in accordance with some embodiments. The respective step is illustrated as the step S13 in the method 10 shown in FIG. 5. In some embodiments, the isolation structure 103 and the doped regions 107 are covered by the mask material 109. Then, a patterned mask 111 with openings 114 is formed over the mask material 109, in accordance with some embodiments. In some embodiments, the mask material 109 is partially exposed by the openings 114 of the patterned mask 111.

In some embodiments, the mask material 109 includes silicon nitride, silicon oxide, silicon oxynitride, another suitable material, or a combination thereof. In some embodiments, the mask material 109 and the patterned mask 111 include different materials so that the etching selectivities may be different in the subsequent etching process. In some embodiments, the mask material 109 is formed by a deposition process, such as a chemical vapor deposition (CVD) process, a physical vapor deposition (PVD) process, an atomic layer deposition (ALD) process, a spin-on coating process, or another suitable deposition process.

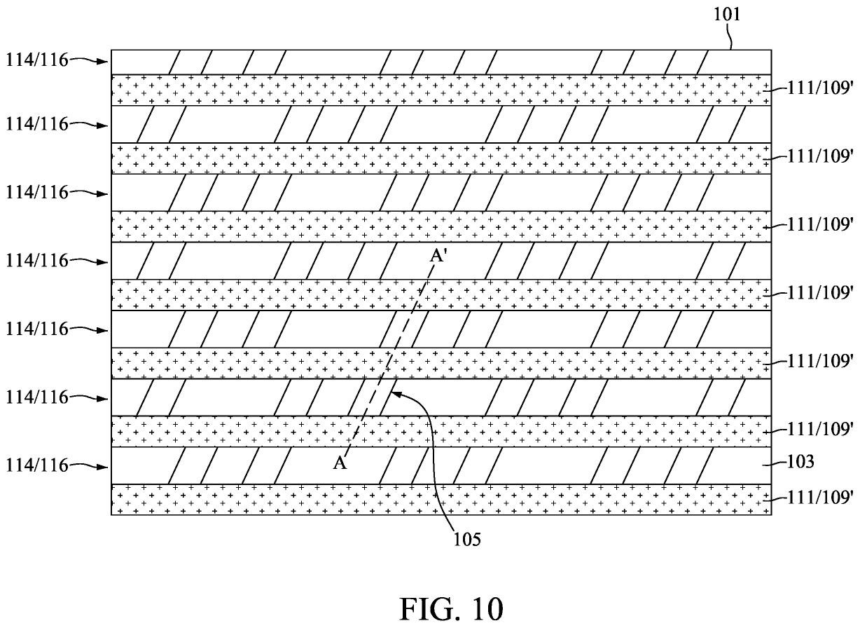

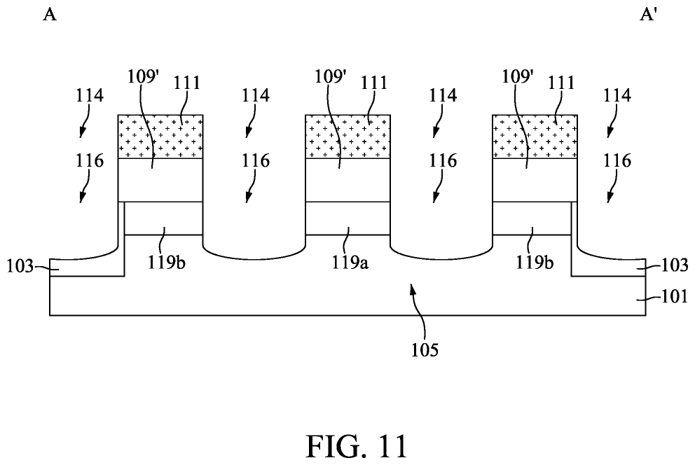

Next, the mask material 109 and the semiconductor substrate 101 are etched to form a plurality of trenches 116 by using the patterned mask 111 as an etching mask, as shown in FIGS. 10 and 11 in accordance with some embodiments. In some embodiments, the trenches 116 are parallel to each other. In some embodiments, the trenches 116 extend across the doped regions 107 in the active areas 105 to form the source/drain regions 119a and 119b (the source/drain regions 119a are referred to as first source/drain regions, and the source/drain regions 119b are referred to as second source/drain regions).

In some embodiments, the source/drain regions 119b are located at the opposite end portions of the active areas 105, and the source/drain regions 119a are located at the middle portions of the active areas 105. In some embodiments, the remaining portions of the mask material 109 are referred to as mask layers 109′. In some embodiments, the trenches 116 are formed by a wet etching process, a dry etching process, or a combination thereof. The respective step is illustrated as the step S15 in the method 10 shown in FIG. 5.

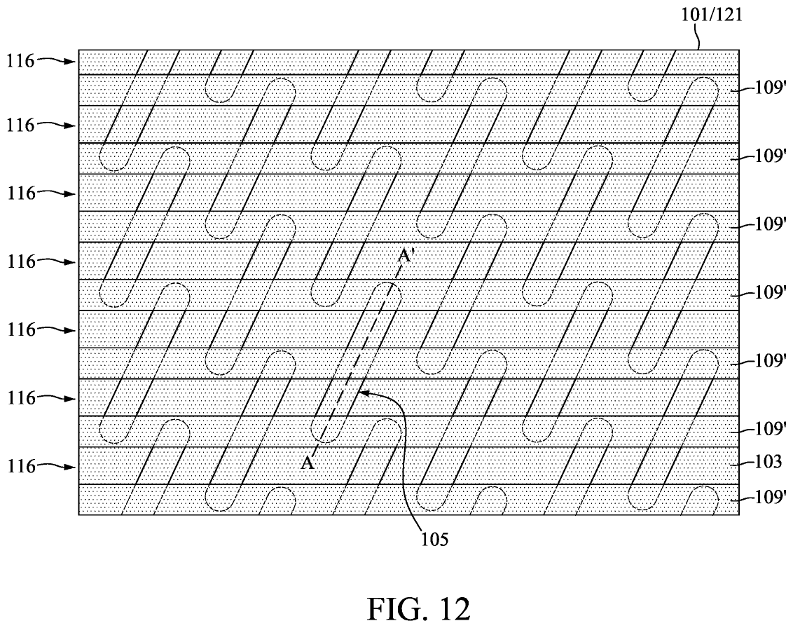

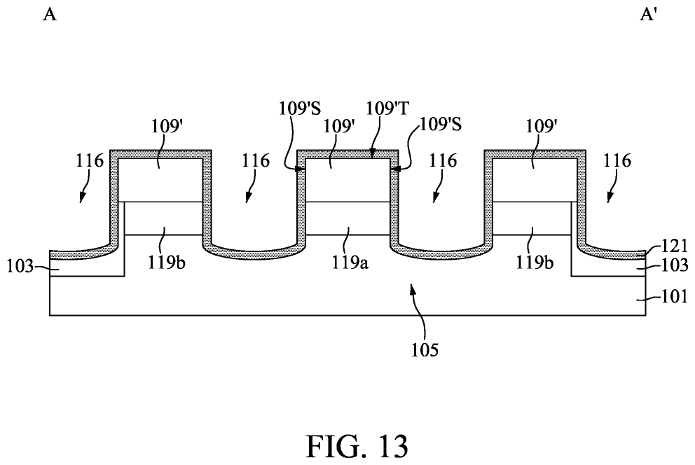

After the trenches 116 are formed, the pattered mask 111 is removed, and a high-k dielectric material 121 is conformally deposited over the structure, as shown in FIGS. 12 and 13 in accordance with some embodiments. The respective step is illustrated as the step S17 in the method 10 shown in FIG. 5. In some embodiments, the patterned mask 111 is removed by a stripping process, an ashing process, an etching process, or another suitable method. After the patterned mask 111 is removed, the top surfaces 109′T and the sidewalls 109'S of the mask layers 109′ are exposed, in accordance with some embodiments.

In some embodiments, the high-k dielectric material 121 is formed lining the trenches 116. In some embodiments, the top surfaces 109′T and the sidewalls 109'S of the mask layers 109′ are covered by the high-k dielectric material 121. In some embodiments, the high-k dielectric material 121 includes HfSiON, HfON, another suitable dielectric material having a dielectric constant (k) higher than that of silicon dioxide, or a combination thereof. In some embodiments, the high-k dielectric material 121 is formed by a deposition process, such as a CVD process, a PVD process, an ALD process, a spin-on coating process, or another suitable deposition process.

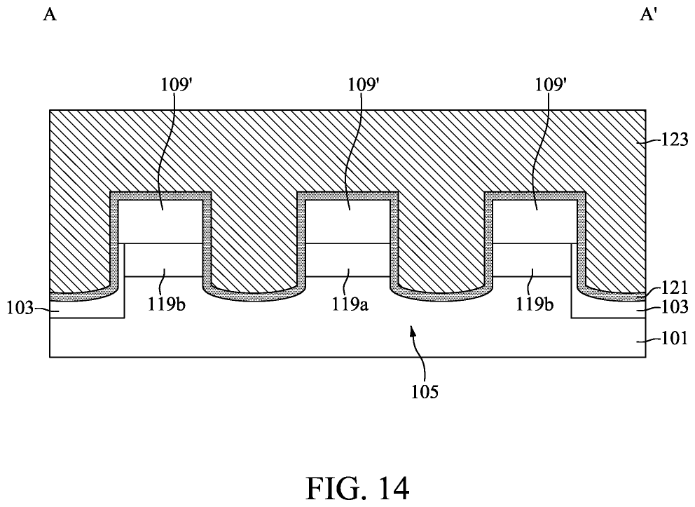

Subsequently, a metal material 123 is formed over the high-k dielectric material 121, as shown in FIG. 14 in accordance with some embodiments. In some embodiments, the remaining portions of the trenches 116 are filled by the metal material 123. In some embodiments, the metal material 123 extends over the top surfaces 109′T of the mask layers 109′ (see FIG. 13). The respective step is illustrated as the step S19 in the method 10 shown in FIG. 5.

In some embodiments, the metal material 123 includes TiN, W, Ru, Al, a RuAl alloy, another suitable metal, or a combination thereof. In some embodiments, the metal material 123 is formed by a deposition process, such as a CVD process, a PVD process, a sputtering process, a plating process, or another suitable deposition process.

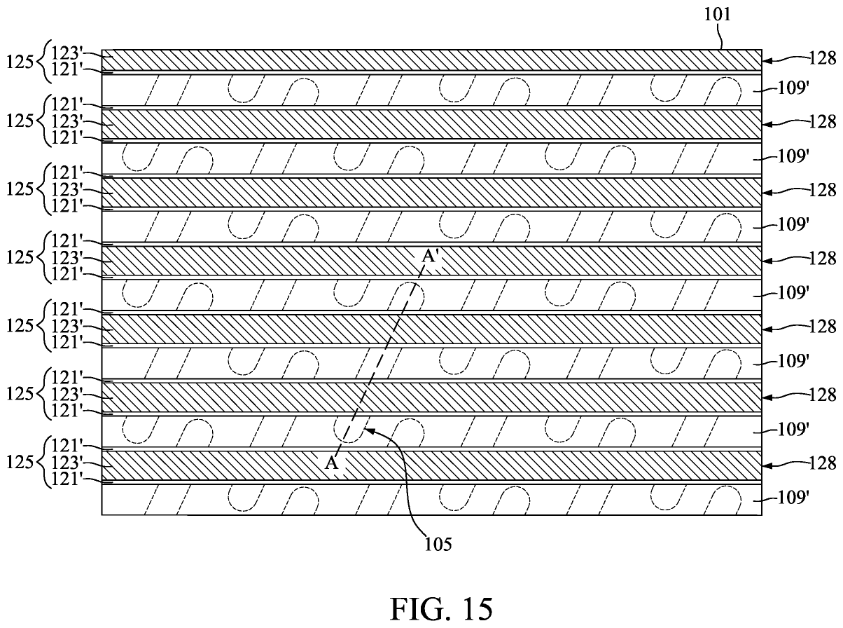

Then, the high-k dielectric material 121 and the metal material 123 are recessed to form a plurality of word line structures 125, as shown in FIGS. 15 and 16 in accordance with some embodiments. The respective step is illustrated as the step S21 in the method 10 shown in FIG. 5. In some embodiments, the high-k dielectric material 121 and the metal material 123 are partially removed by performing an etching process, and the remaining portions of the high-k dielectric material 121′ and the remaining portions of the metal material 123′ collectively form the word line structures 125 (the remaining portions of the high-k dielectric material 121′ are referred to as high-k gate dielectric layers, and the remaining portions of the metal material 123′ are referred to as metal gate electrode layers).

In some embodiments, after the etching process is performed, the top surfaces 109′T of the mask layers 109′ are exposed. In some embodiments, recesses 128 are formed over the word line structures 125. In some embodiments, the recess 128 has a fifth width W5, the metal gate electrode layer 123′ of the word line structure 125 has a sixth width W6, and the fifth width W5 is greater than the sixth width W6.

FIG. 17 is an enlarged view of the portion P3 of the memory device 100 in FIG. 16, in accordance with some embodiments. As shown in FIG. 17, the high-k gate dielectric layer 121′ of the word line structure 125 has a first width W1 over the top surface 123′T of the metal gate electrode layer 123′ of the word line structure 125, and a second width W2 below the top surface 123′T of the metal gate electrode layer 123′ of the word line structure 125. In some embodiments, the second width W2 is greater than the first width W1.

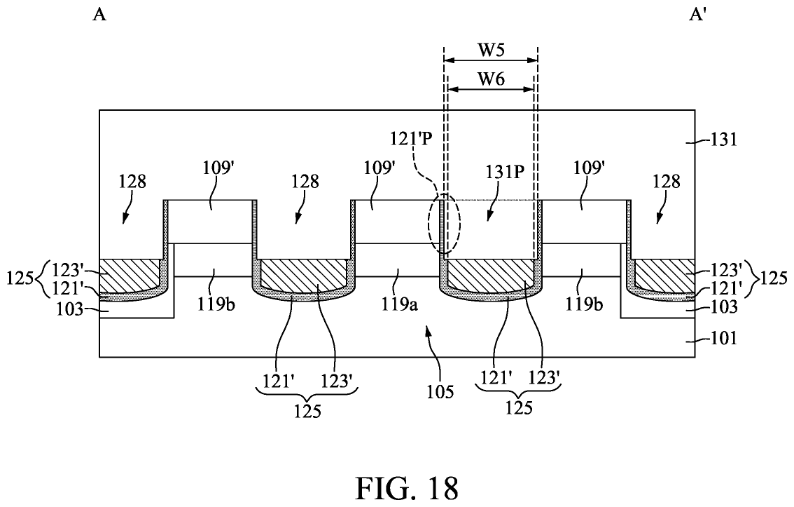

Next, a dielectric layer 131 is formed covering the mask layers 109′ and the word line structures 125, as shown in FIG. 18 in accordance with some embodiments. The respective step is illustrated as the step S23 in the method 10 shown in FIG. 5. In some embodiments, the recesses 128 are filled by portions of the dielectric layer 131, such as the portion 131P of the dielectric layer 131. In this case, the dotted line indicating the boundary of the portion 131P in FIG. 18 is used to clarify the disclosure. No obvious interface exists in the dielectric layer 131.

Each of the high-k gate dielectric layers 121′ has a portion sandwiched between the adjacent mask layer 109′ and the portion of the dielectric layer 131 filled in the recess 128, such as the portion 121′P of the high-k gate dielectric layers 121′, as shown in FIG. 18 in accordance with some embodiments. In some embodiments, the portion 131P of the dielectric layer 131 has a fifth width W5, the metal gate electrode layer 123′ of the word line structure 125 has a sixth width W6, and the fifth width W5 is greater than the sixth width W6. In addition, in some embodiments, the dielectric layer 131 includes silicon oxide, silicon nitride, silicon oxynitride, another suitable dielectric material, or a combination thereof. In addition, the dielectric layer 131 may be formed by a deposition process, such as a CVD process, a PVD process, an ALD process, a spin-on coating process, or another suitable deposition process.

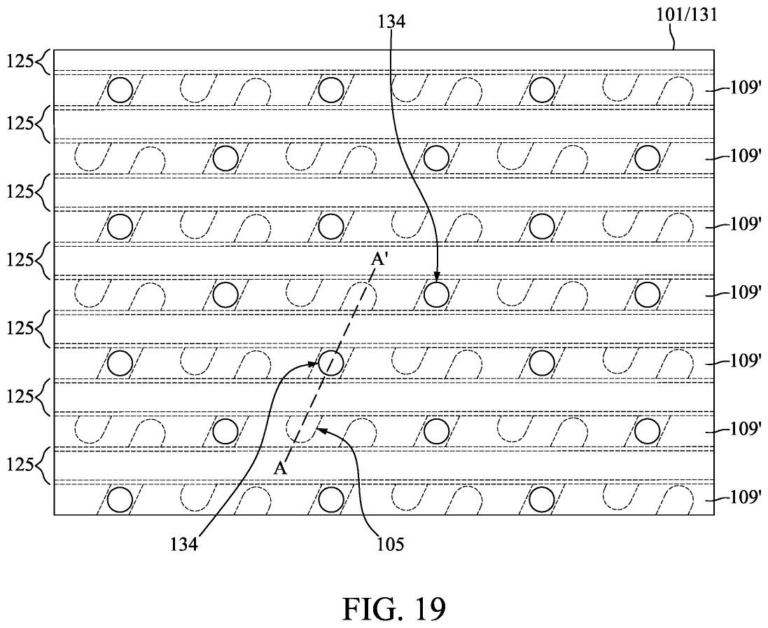

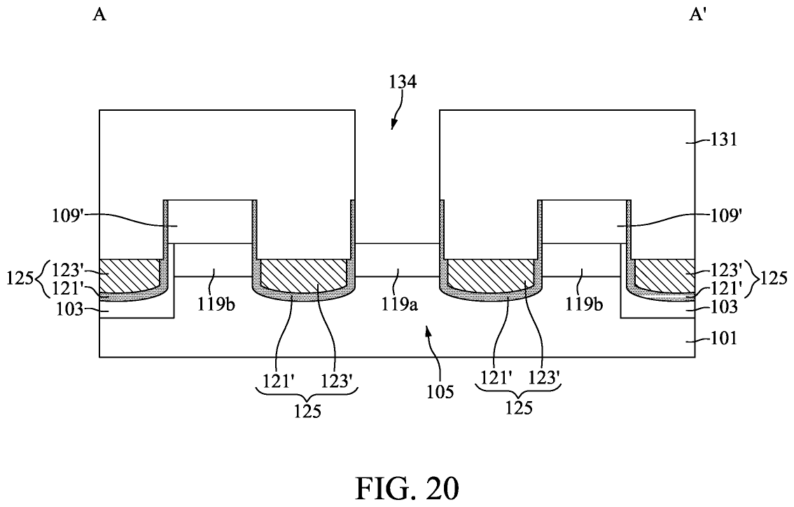

Subsequently, a plurality of bit line contact openings 134 are formed to expose the source/drain regions 119a, as shown in FIGS. 19 and 20 in accordance with some embodiments. The formation of the openings 134 may include forming a patterned mask (not shown) over the dielectric layer 131, and etching the dielectric layer 131 by using the patterned mask as a mask. The etching process may be a wet etching process, a dry etching process, or a combination thereof. After the bit line contact openings 134 are formed, the pattered mask may be removed.

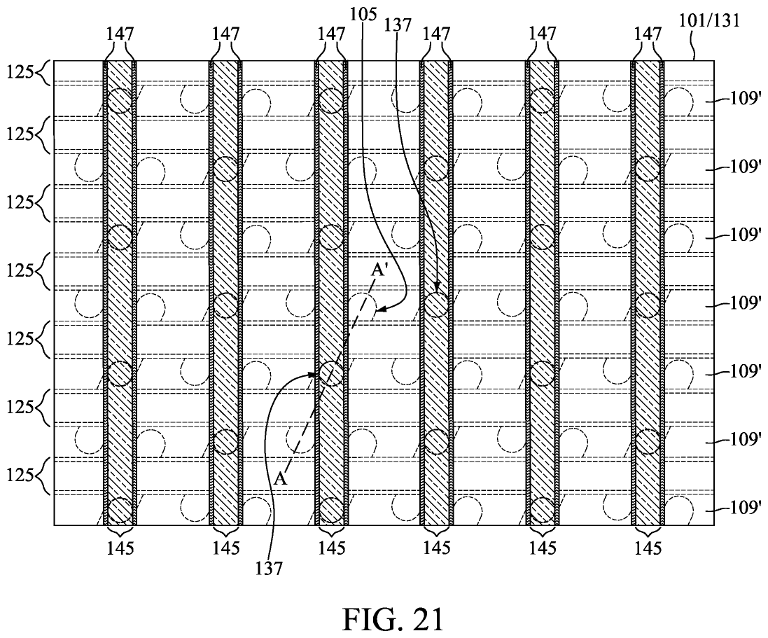

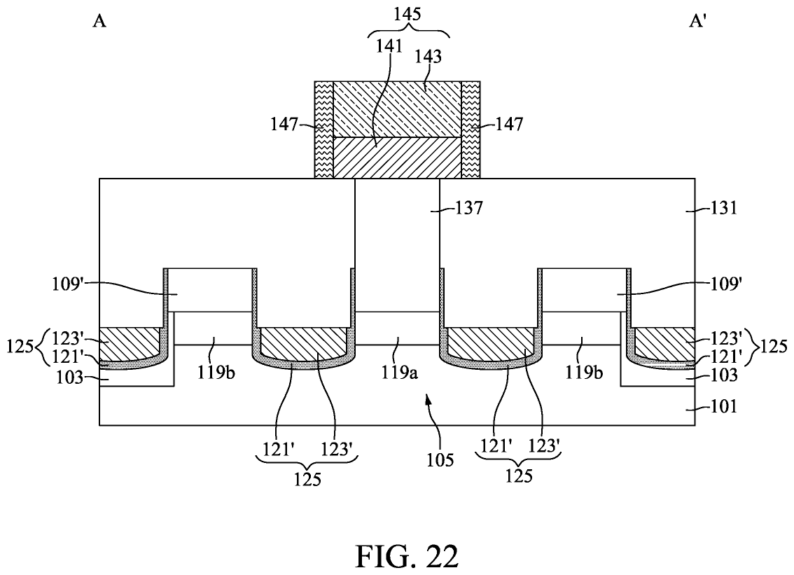

Then, a plurality of bit line contacts 137 are formed in the bit line contact openings 134, and a plurality of bit line structures 145 are formed over the bit line contacts 137, as shown in FIGS. 21 and 22 in accordance with some embodiments. The respective steps are illustrated as the steps S25 and S27 in the method 10 shown in FIG. 5. In some embodiments, each of the bit line structures 145 includes a lower bit line layer 141 and an upper bit line layer 143 disposed over the lower bit line layer 141. In some embodiments, the bit line structures 145 are electrically connected to the source/drain regions 119a.

In some embodiments, the bit line contacts 137 include polysilicon, W, Al, Cu, Ni, Co, another suitable conductive material, or a combination thereof. The formation of the bit line contacts 137 may include depositing a bit line contact material (not shown) in the bit line contact openings 134 and over the dielectric layer 131, and performing a planarization process to remove excess portions of the bit line contact material outside the bit line contact openings 134. The deposition process may include a CVD process, a PVD process, an ALD process, a spin-on coating process, or another suitable deposition process. The planarization process may include a chemical mechanical polishing (CMP) process.

Moreover, the formation of the bit line structures 145 may include forming a lower bit line material (not shown) over the dielectric layer 131, forming an upper bit line material (not shown) over the lower bit line material, forming a patterned mask (not shown) over the upper bit line material, and etching the upper bit line material and the lower bit line material by using the patterned mask as a mask. In some embodiments, the remaining portions of the lower bit line material are referred to as the lower bit line layers 141, and the remaining portions of the upper bit line material are referred to as the upper bit line layers 143. After the bit line structures 145 are formed, the pattered mask may be removed. In some embodiments, the lower bit line layers 141 include TiN, TaN, TaC, TiC, another suitable conductive material, or a combination thereof. In some embodiments, the upper bit line layers 143 include W, Ti, Ni, Co, another suitable conductive material, or a combination thereof.

Next, a plurality of dielectric spacers 147 are formed on the sidewalls of the bit line structures 145, as shown in FIGS. 21 and 22 in accordance with some embodiments. In some embodiments, the dielectric spacers 147 include a doped spin-on-glass (SOG) material, such as phosphosilicate glass (PSG), borophosphosilicate glass (BPSG). In some embodiments, the dielectric spacers 147 are formed by a deposition process, and a subsequent planarization process. The deposition process may include a CVD process, a PVD process, an ALD process, a spin-on coating process, or another suitable deposition process. The planarization process may include a CMP process. The planarization process may be performed to expose the top surfaces of the bit line structures 145.

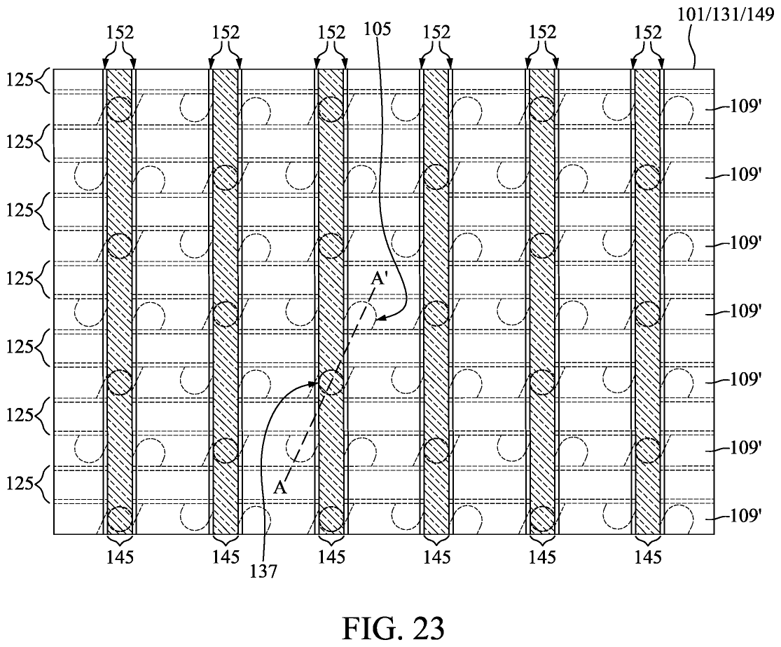

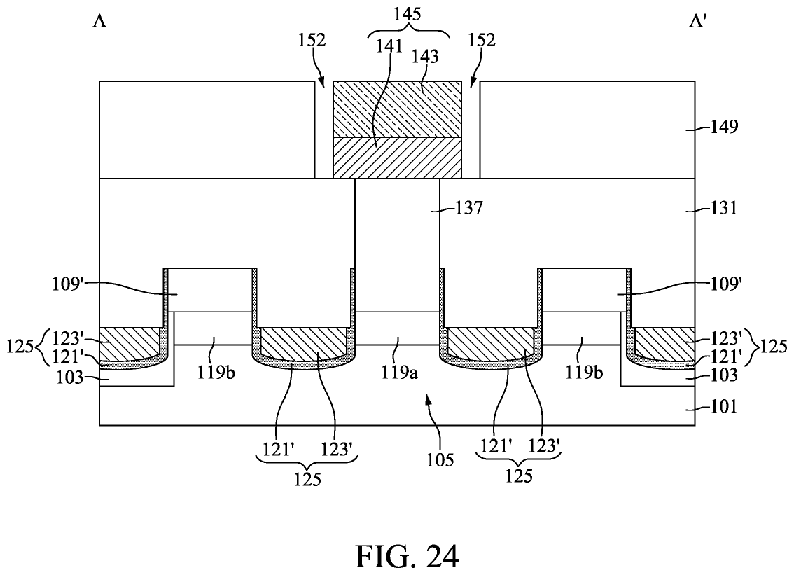

Subsequently, a dielectric layer 149 is formed surrounding the dielectric spacers 147 and the bit line structures 145, and the dielectric spacers 147 are removed to form air gaps 152 between the bit line structures 145 and the dielectric layer 149, as shown in FIGS. 23 and 24 in accordance with some embodiments. In some embodiments, the air gaps 152 are formed on the sidewalls of the bit line structures 145, and the bit line structures 145 are separated from the dielectric layer 149 by the air gaps 152.

In some embodiments, the dielectric layer 149 includes silicon oxide, silicon nitride, silicon oxynitride, another suitable dielectric material, or a combination thereof. Moreover, the dielectric layer 149 is formed by a deposition process, and a subsequent planarization process. The deposition process may include a CVD process, a PVD process, an ALD process, a spin-on coating process, or another suitable deposition process. The planarization process may include a CMP process. After the planarization process, the top surface of the dielectric layer 149 is coplanar with the top surfaces of the bit line structures 145 and the top surfaces of the dielectric spacers 147.

In some embodiments, the dielectric spacers 147 are removed by a vapor phase hydrofluoric acid (VHF) etching process after the dielectric layer 149 is formed. During the etching process, VHF is used as an etchant, and the dielectric spacers 147 have a high selectivity against the dielectric layer 149. Therefore, the dielectric spacers 147 are removed by the etching process, while the dielectric layer 149 may be substantially left, such that the air gaps 152 are obtained.

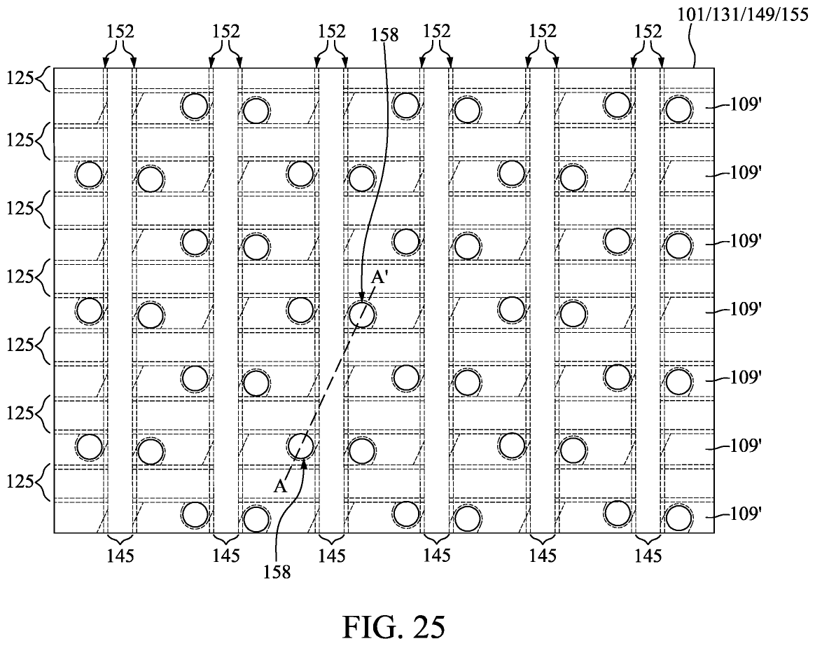

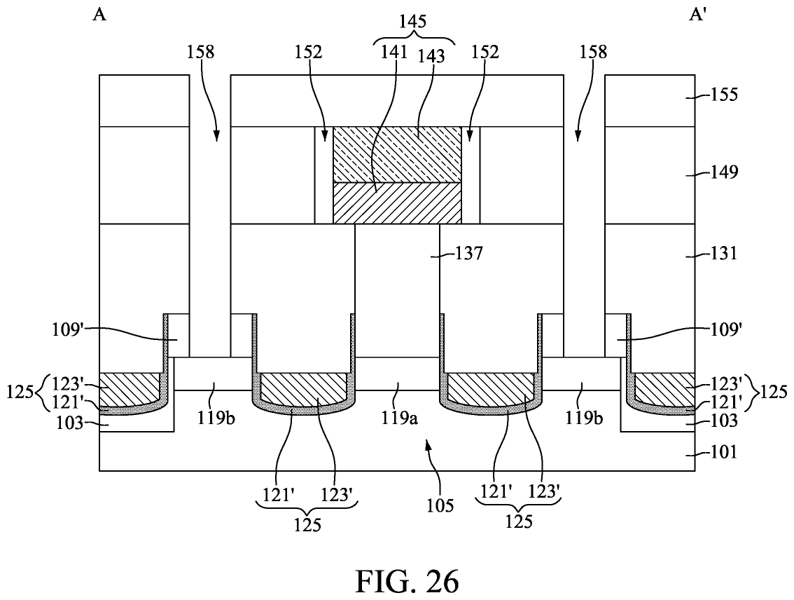

Then, the dielectric layer 155 is formed over the dielectric layer 149 to seal the air gaps 152, and a plurality of capacitor contact openings 158 are formed to expose the source/drain regions 119b, as shown in FIGS. 25 and 26 in accordance with some embodiments. Some materials and processes used to form the dielectric layer 155 are similar to, or the same as those used to form the dielectric layer 149, and details thereof are not repeated herein. In some embodiments, the dielectric layer 155 is formed by a spin-on coating process, and the air gaps 152 with high aspect ratios are sealed by the dielectric layer 155 with the air gaps 152 remain therein rather than filled up by the dielectric layer 155.

In some embodiments, the capacitor contact openings 158 are formed penetrating through the dielectric layers 155, 149 and 131, and the mask layers 109′ over the source/drain regions 119b. The formation of the capacitor contact openings 158 may include forming a patterned mask (not shown) over the dielectric layer 155, and etching the dielectric layer 155 by using the patterned mask as a mask. The etching process may be a wet etching process, a dry etching process, or a combination thereof. After the capacitor contact openings 158 are formed, the pattered mask may be removed.

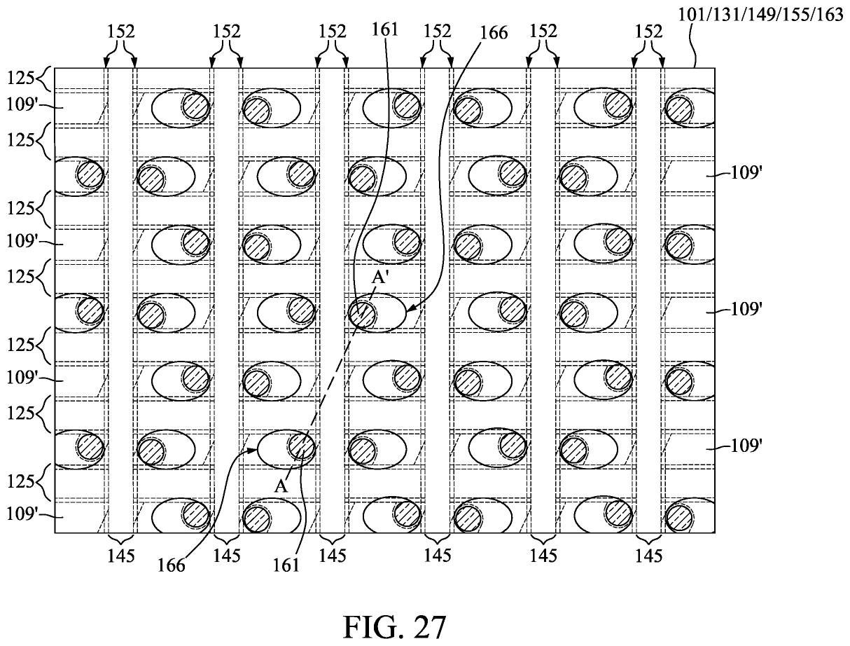

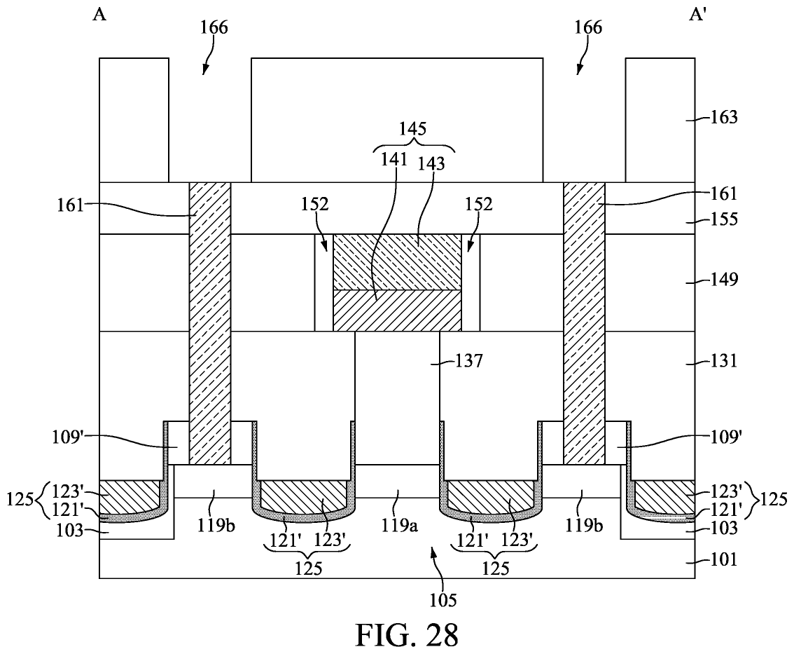

Next, a plurality of capacitor contacts 161 are formed in the capacitor contact openings 158, and a dielectric layer 163 is formed over the dielectric layer 155 to cover the capacitor contacts 161, as shown in FIGS. 27 and 28 in accordance with some embodiments. In some embodiments, the capacitor contacts 161 electrically connect the source/drain regions 119b to the subsequently formed capacitors. The respective step is illustrated as the step S29 in the method 10 shown in FIG. 5.

In some embodiments, the capacitor contacts 161 are made of a conductive material, such as Cu, W, Al, Ti, Ta, Au, Ag, another suitable conductive material, or a combination thereof. The capacitor contacts 161 may be formed by a deposition process and a subsequent planarization process. The deposition process may include a CVD process, a PVD process, a sputtering process, a plating process, or another suitable process. The planarization process may be a CMP process. Some materials and processes used to form the dielectric layer 163 are similar to, or the same as those used to form the dielectric layer 155, and details thereof are not repeated herein.

Still referring to FIGS. 27 and 28, a plurality of capacitor openings 166 are formed penetrating through the dielectric layer 163 to expose the capacitor contacts 161, in accordance with some embodiments. The formation of the capacitor openings 166 may include forming a patterned mask (not shown) over the dielectric layer 163, and etching the dielectric layer 163 by using the patterned mask as a mask to expose the capacitor contacts 161. The etching process may be a wet etching process, a dry etching process, or a combination thereof. After the capacitor openings 166 are formed, the pattered mask may be removed.

Subsequently, referring back to FIGS. 1 and 2, a plurality of capacitors 177 are formed in the capacitor openings 166 in the dielectric layer 163, in accordance with some embodiments. As mentioned above, each of the capacitors 177 includes a bottom electrode 171, a top electrode 175, and a dielectric layer 173 sandwiched between the bottom electrode 171 and the top electrode 175. The respective step is illustrated as the step S31 in the method 10 shown in FIG. 5.

In some embodiments, the top electrodes 175, the dielectric layers 173, and the bottom electrodes 171 collectively form the capacitors 177 electrically connected to the source/drain regions 119b. The formation of the capacitors 177 may include sequentially depositing a conductive material, a dielectric material and another conductive material in the capacitor openings 166 (see FIGS. 27 and 28) and extending over the dielectric layer 163, and performing a planarization process (e.g., a CMP process) to remove excess portions of the two conductive materials and the dielectric material.

In some embodiments, the bottom electrodes 171 include TiN or another suitable conductive material. In some embodiments, the dielectric layers 173 include a dielectric material, such as SiO₂, HfO₂, Al₂O₃, ZrO₂, another suitable dielectric material, or a combination thereof. In some embodiments, the top electrodes 175 include TiN, low-stress SiGe, another suitable conductive material, or a combination thereof. After the capacitors 177 are formed, the memory device 100 is obtained. In some embodiments, the memory device 100 is part of a DRAM.

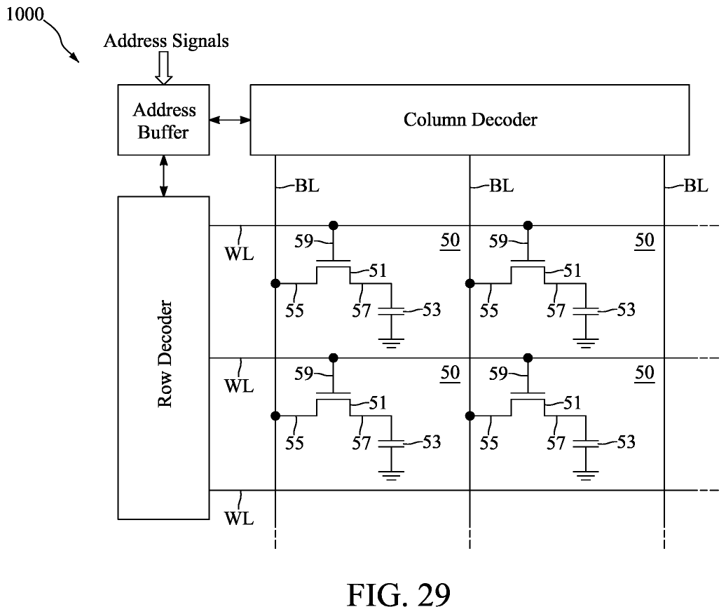

FIG. 29 is a partial schematic illustration of an exemplary integrated circuit, such as a memory device 1000, including an array of memory cells 50 in accordance with some embodiments. In some embodiments, the memory device 1000 includes a DRAM. In some embodiments, the memory device 1000 includes a number of memory cells 50 arranged in a grid pattern and including a number of rows and columns. The number of memory cells 50 may vary depending on system requirements and fabrication technology.

In some embodiments, each of the memory cells 50 includes an access device and a storage device. The access device is configured to provide controlled access to the storage device. In particular, the access device is a field effect transistor (FET) 51 and the storage device is a capacitor 53, in accordance with some embodiments. In each of the memory cells 50, the FET 51 includes a drain 55, a source 57 and a gate 59. One terminal of the capacitor 53 is electrically connected to the source 57 of the FET 51, and the other terminal of the capacitor 53 may be electrically connected to the ground. In addition, in each of the memory cells 50, the gate 59 of the FET 51 is electrically connected to a word line WL, and the drain 55 of the FET 51 is electrically connected to a bit line BL.

The above description mentions the terminal of the FET 51 electrically connected to the capacitor 53 is the source 57, and the terminal of the FET 51 electrically connected to the bit line BL is the drain 55. However, during read and write operations, the terminal of the FET 51 electrically connected to the capacitor 53 may be the drain, and the terminal of the FET 51 electrically connected to the bit line BL may be the source. That is, either terminal of the FET 51 could be a source or a drain depending on the manner in which the FET 51 is being controlled by the voltages applied to the source, the drain and the gate.

By controlling the voltage at the gate 59 via the word line WL, a voltage potential may be created across the FET 30 such that the electrical charge can flow from the drain 55 to the capacitor 53. Therefore, the electrical charge stored in the capacitor 53 may be interpreted as a binary data value in the memory cell 30. For example, a positive charge above a threshold voltage stored in the capacitor 53 may be interpreted as binary “1.” If the charge in the capacitor 53 is below the threshold value, a binary value of “0” is said to be stored in the memory cell 30.

The bit lines BL are configured to read and write data to and from the memory cells 50. The word lines WL are configured to activate the FET 51 to access a particular row of the memory cells 50. Accordingly, the memory device 1000 also includes a periphery circuit region which may include an address buffer, a row decoder and a column decoder. The row decoder and the column decoder selectively access the memory cells 50 in response to address signals that are provided to the address buffer during read, write and refresh operations. The address signals are typically provided by an external controller such as a microprocessor or another type of memory controller.

Referring back to FIGS. 1 and 2, the memory device 100 is located in an array region. The array region may be any of the regions of the memory cells 50 in the memory device 1000.

Embodiments of the memory device 100 and method for preparing the same are provided in the disclosure. In some embodiments, the memory device 100 includes the word line structures 125 disposed in the semiconductor substrate 101, and the word line structures 125 include the metal gate electrode layers 123′ and the high-k gate dielectric layers 121′ surrounding the metal gate electrode layers 123′. Therefore, gate-to-substrate leakage current can be reduced while suppressing channel leakage current and enlarging the channel length, which are advantages of the buried word line structures (i.e., the word line structures 125). In addition, the air gaps 152 may help to reduce parasitic capacitance and correspondingly improve device performance (e.g., by reducing signal noise). As a result, the performance of the memory device 100 can be improved.

In one embodiment of the present disclosure, a memory device is provided. The memory device includes a semiconductor substrate having an active area, and a word line structure extending across the active area. The word line structure includes a metal gate electrode layer and a high-k gate dielectric layer surrounding the metal gate electrode layer. The memory device also includes a first source/drain region and a second source/drain region disposed in the active area and at opposite sides of the word line structure. The memory device further includes a bit line structure disposed over and electrically connected to the first source/drain region, and a capacitor disposed over and electrically connected to the second source/drain region.

In another embodiment of the present disclosure, a memory device is provided. The memory device includes a semiconductor substrate having an active area, and a word line structure extending across the active area. The word line structure includes a metal gate electrode layer and a high-k gate dielectric layer surrounding the metal gate electrode layer. The memory device also includes a first source/drain region and a second source/drain region disposed in the active area and at opposite sides of the word line structure. The memory device further includes a dielectric layer disposed over the semiconductor substrate and covering the word line structure. An interface between the dielectric layer and the high-k gate dielectric layer is substantially level with an interface between the dielectric layer and the metal gate electrode layer. In addition, the memory device includes a bit line structure disposed over and electrically connected to the first source/drain region, and a capacitor disposed over and electrically connected to the second source/drain region.

In yet another embodiment of the present disclosure, a method for preparing a memory device is provided. The method includes forming a doped region in a semiconductor substrate, and performing a first etching process on the semiconductor substrate to form a trench. The trench extends across the doped region such that a first source/drain region and a second source/drain region are formed in the doped region and at opposite sides of the trench. The method also includes forming a high-k dielectric material lining the trench, and filling the trench with a metal material. The method further includes performing a second etching process on the high-k dielectric material and the metal material to form a recess. Remaining portions of the high-k dielectric material and the metal material form a high-k gate dielectric layer of a word line structure and a metal gate electrode layer of the word line structure, respectively, and a width of the recess is greater than a width of the metal gate electrode layer. In addition, the method includes forming a bit line structure over and electrically connected to the first source/drain region, and forming a capacitor over and electrically connected to the second source/drain region.

The embodiments of the present disclosure have some advantageous features. By forming word line structures with high-k gate dielectric layers in array regions, gate-to-substrate leakage current can be reduced while suppressing channel leakage current and enlarging the channel length. As a result, the performance of the memory device can be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein May be utilized according to the present disclosure. Accordingly, the appended claims are intended to include within their scope such processes, machines, manufacture, compositions of matter, means, methods, and steps.

What is claimed is:

1. A memory device, comprising:
a semiconductor substrate having an active area;
a word line structure extending across the active area, wherein the word line structure comprises a metal gate electrode layer and a high-k gate dielectric layer surrounding the metal gate electrode layer;
a first source/drain region and a second source/drain region disposed in the active area and at opposite sides of the word line structure;
a bit line structure disposed over and electrically connected to the first source/drain region; and
a capacitor disposed over and electrically connected to the second source/drain region.

2. The memory device of claim 1, wherein the high-k gate dielectric layer has a first width over a top surface of the metal gate electrode and a second width below the top surface of the metal gate electrode, and wherein the second width is greater than the first width.

3. The memory device of claim 1, further comprising:
a bit line contact disposed between the first source/drain region and the bit line structure, wherein the bit line contact is in direct contact with the high-k gate dielectric layer.

4. The memory device of claim 3, further comprising:
a dielectric layer covering the word line structure, wherein a portion of the high-k gate dielectric layer is sandwiched between the dielectric layer and the bit line contact.

5. The memory device of claim 4, wherein the dielectric layer has a portion surrounded by the high-k gate dielectric layer, and a width of the portion of the dielectric layer is greater than a width of the metal gate electrode layer.

6. The memory device of claim 1, further comprising:
a mask layer disposed between the second source/drain region and the capacitor, wherein the mask layer is in direct contact with the high-k gate dielectric layer.

7. The memory device of claim 6, wherein the high-k gate dielectric layer has a third width adjacent to the mask layer and a fourth width adjacent to the second source/drain region, and wherein the fourth width is greater than the third width.

8. The memory device of claim 6, wherein a top surface of the high-k gate dielectric layer is substantially level with a top surface of the mask layer.

9. A memory device, comprising:
a semiconductor substrate having an active area;
a word line structure extending across the active area, wherein the word line structure comprises a metal gate electrode layer and a high-k gate dielectric layer surrounding the metal gate electrode layer;
a first source/drain region and a second source/drain region disposed in the active area and at opposite sides of the word line structure;
a dielectric layer disposed over the semiconductor substrate and covering the word line structure, wherein an interface between the dielectric layer and the high-k gate dielectric layer is substantially level with an interface between the dielectric layer and the metal gate electrode layer;
a bit line structure disposed over the dielectric layer and electrically connected to the first source/drain region; and
a capacitor disposed over the dielectric layer and electrically connected to the second source/drain region.

10. The memory device of claim 9, wherein the high-k gate dielectric layer has a first width over a top surface of the metal gate electrode and a second width below the top surface of the metal gate electrode, and wherein the second width is greater than the first width.

11. The memory device of claim 9, further comprising:
a bit line contact penetrating through the dielectric layer to electrically connect the first source/drain region and the bit line structure, wherein the bit line contact is in direct contact with the high-k gate dielectric layer.

12. The memory device of claim 9, further comprising:
a mask layer disposed between the second source/drain region and the dielectric layer, wherein the mask layer is in direct contact with the high-k gate dielectric layer.

13. The memory device of claim 12, wherein the high-k gate dielectric layer has a third width adjacent to the mask layer and a fourth width adjacent to the second source/drain region, and wherein the fourth width is greater than the third width.

14. The memory device of claim 12, wherein a top surface of the high-k gate dielectric layer is substantially level with a top surface of the mask layer.

15. The memory device of claim 12, further comprising:
a capacitor contact penetrating through the dielectric layer and the mask layer to electrically connect the second source/drain region and the capacitor.
